(19) United States
(12) Patent Application Publication
(10) Pub. No.: US 2025/0038072 A1
(43) Pub. Date: Jan. 30, 2025

(54) SEMICONDUCTOR DIE AND METHOD FOR FORMING THE SAME

(71) Applicant: TAIWAN SEMICONDUCTOR MANUFACTURING COMPANY, LTD., Hsinchu (TW)

(72) Inventors: Hsin-Yuan LEE, Hsinchu City (TW); Chih-Kai YANG, Taipei City (TW); Ken-Hsien HSIEH, Taipei City (TW); Ya Hui CHANG, Hsinchu City (TW)

(73) Assignee: TAIWAN SEMICONDUCTOR MANUFACTURING COMPANY, LTD., Hsinchu (TW)

(21) Appl. No.: 18/360,178

(22) Filed: Jul. 27, 2023

(51) Int. Cl. H01L 23/48; H01L 21/768; H01L 23/367

(52) U.S. Cl. CPC H01L 23/481; H01L 21/76898; H01L 23/367

(57) ABSTRACT

A semiconductor die includes a substrate, a semiconductor device, a back-end-of-line (BEOL) structure, and a heat dissipation structure. The substrate includes a device region and a non-device region. The BEOL structure includes a plurality of metallization layers. Each of the metallization layers includes a dielectric layer, interconnect features, and metal patterns. The interconnect features is in the dielectric layer and over the device region of the substrate, in which the interconnect features are electrically connected with the semiconductor device. The metal patterns are in the dielectric layer and over the non-device region of the substrate, in which the metal patterns are electrically isolated from the semiconductor device. The heat dissipation structure is over the non-device region of the substrate and extending through at least two of the metallization layers, in which the heat dissipation structure is in contact with the metal patterns of one of the metallization layers.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a wafer in accordance with some embodiments.

FIG. 1B is an enlarged view of the top view of FIG. 1A in accordance with some embodiments.

FIG. 1C is a cross-sectional view of FIG. 1A in accordance with some embodiments.

FIGS. 2A to 7 illustrate a semiconductor die in various stages of fabrication in accordance with some embodiments of the present disclosure.

FIG. 8 illustrates a semiconductor die in accordance with some embodiments of the present disclosure.

FIGS. 9 to 10 illustrate a semiconductor die in various stages of fabrication in accordance with some embodiments of the present disclosure.

FIGS. 11 to 13 illustrate a semiconductor die in various stages of fabrication in accordance with some embodiments of the present disclosure.

FIGS. 14 to 16 illustrate a semiconductor die in various stages of fabrication in accordance with some embodiments of the present disclosure.

FIG. 17 is a top view of a semiconductor die in accordance with some embodiments.

FIG. 18 is a top view of a semiconductor die in accordance with some embodiments.

FIGS. 19A to 20B illustrate a semiconductor die in various stages of fabrication in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

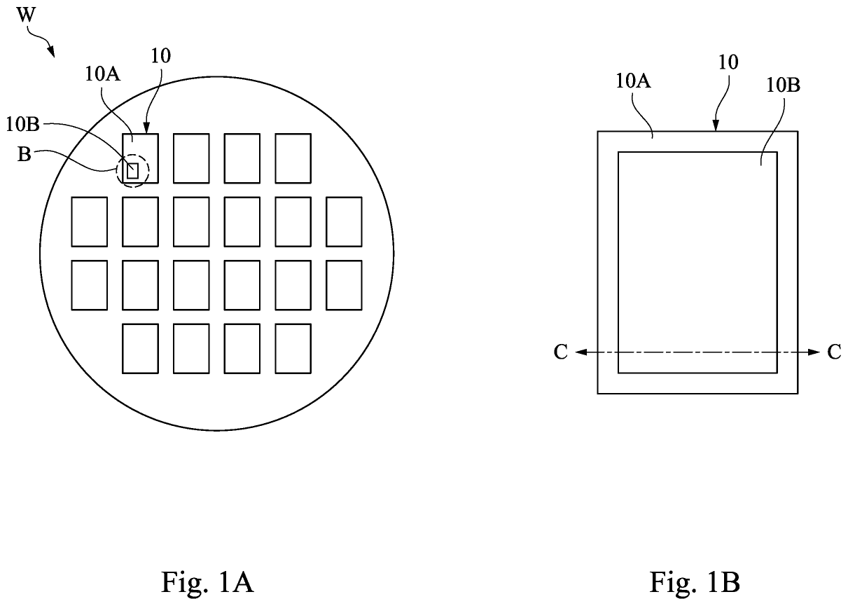

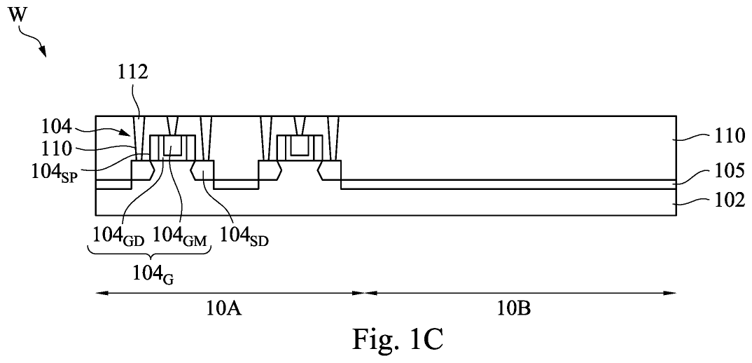

FIG. 1A is a top view of a wafer in accordance with some embodiments. FIG. 1B is an enlarged view of the top view o of FIG. 1A in accordance with some embodiments. FIG. 1C is a cross-sectional view of FIG. 1A in accordance with some embodiments. In greater detail, FIG. 1B is an enlarged view of the dotted region B of FIG. 1A, and FIG. 1C is a cross-sectional view of line C-C of FIG. 1B, respectively.

Shown there is a wafer W. In some embodiments, the wafer W may be a semiconductor wafer. The wafer W includes a plurality of die regions 10 (or chip regions). In some embodiments, each die region 10 can be regarded as an exposure field. Each die region 10 may be singulated into individual die after the semiconductor manufacturing processes performed on the wafer W are finished.

In the depicted embodiments, the wafer W may be exposed to extreme ultraviolet (EUV) radiation (light) using a mask (not shown). The image of the mask can be transferred to the wafer W multiple times using multiple exposures with the mask. For example, in FIG. 1A, the mask is used in multiple exposure processes to pattern the wafer W, such that the pattern of the mask image region is transferred to various fields of the wafer W (e.g., the die regions 10). Each field (e.g., the die regions 10) may correspond to at least one semiconductor device (or at least one integrated circuit device). For example, an exposure tool (such as a stepper or a scanner) processes one field (such as exposing a die region 10 of the wafer W to the mask), then processes the next field (such as exposing another die region 10 of the wafer W to the mask), and so on. In the present example, the wafer W may include a resist layer disposed over a substrate, where the pattern of the mask image region is transferred to the resist layer.

In some embodiments, each die region 10 may include a device region 10A and a non-device region 10B. In greater detail, the non-device region 10B is within the device region 10A and is surrounded by the device region 10A. For example, as shown in FIG. 1B, in a top view, the device region 10A surrounds at least four sides of the non-device region 10B. In some embodiments, the device region 10A may include active device, such as a diode, a metal-oxide-semiconductor field effect transistor (MOSFET), a complementary MOS (CMOS) transistor, a bipolar junction transistor (BJT), a laterally diffused MOS (LDMOS) transistor, a high power MOS transistor, a fin-like field effect transistor (FinFET), other integrated circuit component, or combination thereof. In other embodiments, the device region 10A may include passive device, such as a resistor, a capacitor, an inductor, or combination thereof. In some embodiments, the non-device region 10B may be free of the active device and the passive device described above.

The non-device region 10B of the die region 10 may be a metrology pad region. In one embodiment, the metrology pad region may be an overlay mark region. For example, the overlay mark region may include at least one overlay mark, which is used as a tool for measuring overlay error and to determine whether the photoresist pattern is precisely aligned with the previous layer on a wafer after a photolithography process.

In another embodiment, the metrology pad region may be a test critical dimension (TCD) region. For example, the TCD region may include at least one TCD pad. The TCD pad may include a pattern that are sized the same as the interconnect patterns in the device region 10A of the die region 10, and thus the TCD pad can be used as a tool to determine the minimal critical dimension (CD) of the interconnect patterns in the device region 10A of the die region 10.

Because the metrology pad region (e.g., non-device region 10B) is located within a die region 10 of the wafer (see FIG. 1A), the metrology pad region can also be referred to as an in-die metrology pad region. When the metrology pad region is an overlay mark region, the overlay mark region can also be referred to as an in-die overlay mark region. Similarly, when the metrology pad region is a test critical dimension (TCD) region, the TCD region can also be referred to as an in-die TCD region.

Reference is made to FIG. 1C. The wafer W includes a substrate 102. The substrate 102 may comprise, for example, bulk silicon, doped or un-doped, or an active layer of a semiconductor-on-insulator (SOI) substrate. Generally, an SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Alternatively, the substrate 102 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, one or more active and/or passive devices 104 (illustrated in FIG. 1C as two transistors) are formed over the device region 10A of the substrate 102 of the wafer W. The one or more active and/or passive devices 104 may include various N-type metal-oxide semiconductor (NMOS) and/or P-type metal-oxide semiconductor (PMOS) devices, such as transistors, capacitors, resistors, diodes, photo-diodes, fuses, and the like. One of ordinary skill in the art will appreciate that the above examples are provided for the purpose of illustration only and are not meant to limit the present disclosure in any manner. Other circuitry may be also formed as appropriate for a given application. In some embodiments, the non-device region 10B of the substrate 102 of the wafer W is free of the one or more active and/or passive devices 104.

In the depicted embodiments, the devices 104 are fin field-effect transistors (FinFET) that are three-dimensional MOSFET structure formed in fin-like strips of semiconductor protrusions referred to as fins 103. The cross-section shown in FIG. 1C is taken along a longitudinal axis of the fin in a direction parallel to the direction of the current flow between the source/drain regions 104_{SD}. The fin 103 may be formed by patterning the substrate 102 using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 103 by etching a trench into the substrate 102 using, for example, reactive ion etching (RIE). In some other embodiments, the devices 104 are planar transistors or gate-all-around (GAA) transistors.

Shallow trench isolation (STI) regions 105 formed on opposing sidewalls of the fin 103 are illustrated in FIG. 1C. STI regions 105 may be formed by depositing one or more dielectric materials (e.g., silicon oxide) to completely fill the trenches around the fins and then recessing the top surface of the dielectric materials. The dielectric materials of the STI regions 105 may be deposited using a high density plasma chemical vapor deposition (HDP-CVD), low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 105 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 105 such that an upper portion of fins 103 protrudes from surrounding insulating STI regions 105. In some cases, the patterned hard mask used to form the fins 103 may also be removed by the planarization process.

In some embodiments, a gate structure 104_{G} of the device 104 illustrated in FIG. 1C is a high-k, metal gate (HKMG) gate structure that may be formed using a gate-last process flow. In a gate-last process flow, a sacrificial dummy gate structure (not shown) is formed after forming the STI regions 105. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 105. As described in greater detail below, the dummy gate structure may be replaced by the metal gate structure 104_{G} as illustrated in FIG. 1C. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

In FIG. 1C, source/drain regions 104_{SD} and spacers 104_{SP} of the device 104 are formed, for example, self-aligned to the dummy gate structures. Spacers 104_{SP} may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 104_{SP} along the sidewalls of the dummy gate structures extending laterally onto a portion of the surface of the fin 103.

Source/drain regions 104_{SD} are semiconductor regions in direct contact with the semiconductor fin 103. In some embodiments, the source/drain regions 104_{SD} may comprise heavily-doped regions and relatively lightly-doped drain extensions, or LDD regions. Generally, the heavily-doped regions are spaced away from the dummy gate structures using the spacers 104_{SP}, whereas the LDD regions may be formed prior to forming spacers 104_{SP} and, hence, extend under the spacers 104_{SP} and, in some embodiments, extend further into a portion of the semiconductor fin 103 below the dummy gate structure. The LDD regions may be formed, for example, by implanting dopants (e.g., As, P. B. In, or the like) using an ion implantation process.

The source/drain regions 104_{SD} may comprise an epitaxially grown region. For example, after forming the LDD regions, the spacers 104_{SP} may be formed and, subsequently, the heavily-doped source and drain regions may be formed self-aligned to the spacers 104_{SP} by first etching the fins to form recesses, and then depositing a crystalline semiconductor material in the recess by a selective epitaxial growth (SEG) process that may fill the recess and may extend further beyond the original surface of the fin 103 to form raised source/drain epitaxy structures. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁴ cm⁻² to 10¹⁶ cm⁻²) of dopants may be introduced into the heavily-doped source/drain regions 104_{SD} either in situ during SEG, or by an ion implantation process performed after the SEG, or by a combination thereof.

Once the source/drain regions 104_{SD} are formed, a first ILD layer (e.g., lower portion of the ILD layer 110) is deposited over the source/drain regions 104_{SD}. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD layer. The metal gate structures 104_{G}, illustrated in FIG. 1C, may then be formed by first removing the dummy gate structures using one or more etching techniques, thereby creating recesses between respective spacers 104_{SP}. Next, a replacement gate dielectric layer 104_{GD} comprising one more dielectrics, followed by a replacement gate metal layer 104_{GM} comprising one or more metals, are deposited to completely fill the recesses. Excess portions of the gate dielectric layer 104_{GD} and gate metal layer 104_{GM} may be removed from over the top surface of first ILD using, for example, a CMP process. The resulting structure, as illustrated in FIG. 1C, may include remaining portions of the gate dielectric layer 104_{GD} and gate metal layer 104_{GM} inlaid between respective spacers 104_{SP}.

The gate dielectric layer 104_{GD} includes, for example, a high-k dielectric material such as oxides and/or silicates of metals (e.g., oxides and/or silicates of Hf, Al, Zr. La, Mg. Ba. Ti, and other metals), silicon nitride, silicon oxide, and the like, or combinations thereof, or multilayers thereof. In some embodiments, the gate metal layer 104_{GM} may be a multilayered metal gate stack comprising a barrier layer, a work function layer, and a gate-fill layer formed successively on top of gate dielectric layer 104_{GD}. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAlC, TiAlN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, PVD, ALD, PEALD, electrochemical plating (ECP), electroless plating and/or the like.

After forming the metal gate structure 104_{G}, a second ILD layer is deposited over the first ILD layer, and these ILD layers are in combination referred to as the ILD layer 110, as illustrated in FIG. 1C. In some embodiments, the insulating materials to form the first ILD layer and the second ILD layer may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer and the second ILD layer may be deposited using any suitable method, such as CVD, physical vapor deposition (PVD), ALD, PEALD, PECVD, SACVD, FCVD, spin-on, and/or the like, or a combination thereof.

As illustrated in FIG. 1C, contacts 112 are formed to make electrical connections to the metal gate structure 104_{G} and the source/drain regions 104_{SD} of devices 104. The contacts 112 may be formed using photolithography, etching and deposition techniques.

For example, a patterned mask may be formed over the ILD layer 110 and used to etch openings that extend through the ILD layer 110 to expose the gate structure 104_{G} as well as the source/drain regions 104_{SD}. Thereafter, conductive liner may be formed in the openings in the ILD layer 110. Subsequently, the openings are filled with a conductive fill material. The liner comprises barrier metals used to reduce out-diffusion of conductive materials from the contacts 112 into the surrounding dielectric materials. In some embodiments, the liner may comprise two barrier metal layers. The first barrier metal comes in contact with the semiconductor material in the source/drain regions 104_{SD} and may be subsequently chemically reacted with the heavily-doped semiconductor in the source/drain regions 104_{SD} to form a low resistance ohmic contact, after which the unreacted metal may be removed. For example, if the heavily-doped semiconductor in the source/drain regions 104_{SD} is silicon or silicon-germanium alloy semiconductor, then the first barrier metal may comprise Ti, Ni, Pt, Co, other suitable metals, or their alloys, and may form silicide with the source/drain regions 104_{SD}. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the ILD layer 110.

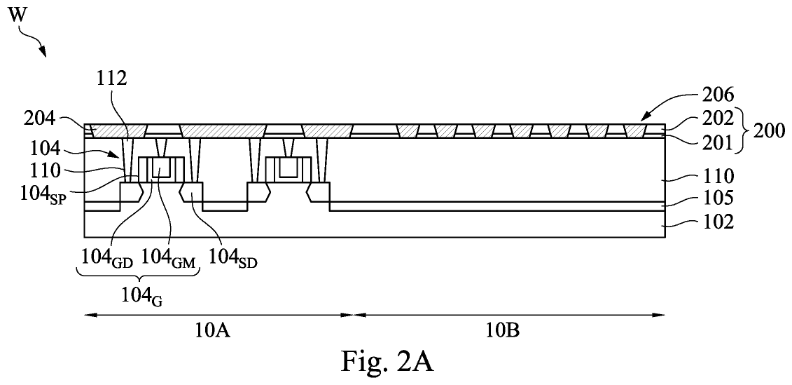

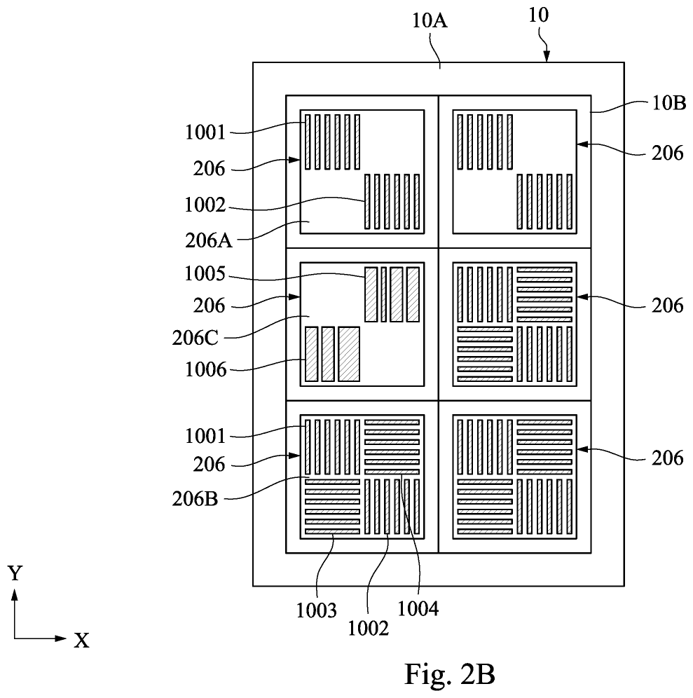

FIGS. 2A to 7 illustrate a semiconductor die in various stages of fabrication in accordance with some embodiments of the present disclosure. It is noted that some elements described in FIGS. 2A to 7 is similar to those described in FIGS. 1A to 1C, such elements are labeled the same, and relevant details will not be repeated for brevity.

Reference is made to FIGS. 2A and 2B, in which FIG. 2A is a cross-sectional view of a die region of a wafer, and FIG. 2B is a top view of a die region of a wafer. In greater detail, FIG. 2A has a same cross-sectional view as FIG. 1C, and FIG. 2B has a same top view as FIG. 1B.

In FIG. 2A, a metallization layer 200 is formed over the structure shown in FIG. 1C. In some embodiments, the metallization layer 200 includes an etch stop layer (ESL) 201 and an inter-metal dielectric (IMD) layer 202 over the ESL 201. In some embodiments, the ESL 201 may be made of, for sample, silicon nitride, silicon carbide, or the like, or a combination thereof. In some embodiments, the IMD layer 202 may be made of, for example, phosphosilicate glass (PSG), borophosphosilicate glass (BPSG), fluorosilicate glass (FSG), SiOxCy, Spin-On-Glass, Spin-On-Polymers, silicon oxide, silicon oxynitride, combinations thereof, or the like, formed by any suitable method, such as spin-on coating, chemical vapor deposition (CVD), plasma-enhanced CVD (PECVD), or the like.

The metallization layer 200 further includes several interconnect features 204, in which each of the interconnect features 204 may penetrate through the ESL 201 and the IMD layer 202, and may be electrically connected to corresponding source/drain regions 104_{SD} and/or gate structure 104_{G} of the devices 104 through the contacts 112. In the embodiments shown in FIG. 2A, the interconnect features 204 are in physical contact with corresponding contacts 112. In some embodiments, the interconnect features 204 are located within the device region 10A of the substrate 102 of the wafer W. That is, the interconnect features 204 are not formed within the non-device region 10B of the substrate 102 of the wafer W.

In the embodiments as discussed in FIGS. 2A and 2B, the non-device region 10B of the substrate 102 of the wafer W may be used as an overlay mark region. In such embodiments, the metallization layer 200 further includes several overlay marks 206 located within the non-device region 10B (e.g., overlay mark region) of the substrate 102 of the wafer W. As shown in the top view of FIG. 2B, shown there are six overlay marks 206 arranged in a 2×3 matrix. However, the number and the arrangement of the overlay marks 206 shown in FIG. 2B are merely used to explain, and are not used to limit the embodiments of the present disclosure. In other embodiments, the more or less overlay marks 206 may be applied, and the overlay marks 206 may also include arrangement different from that described in FIG. 2B.

Still referring to FIG. 2B, the overlay marks 206 may include an overlay mark 206A. In some embodiments, the overlay mark 206A is a grating overlay mark including at least a grating of first features 1001, in which the first features 1001 are disposed periodically in parallel along a first direction (e.g., X direction in FIG. 2B), and each of the first features 1001 has a lengthwise direction along a second direction (e.g., Y direction in FIG. 2B) that is substantially perpendicular to the first direction. More specifically, each of the first features 1001 has a bar pattern that is formed by an unbroken opaque line and the bar patterns are formed by a grating having a plurality of spaced opaque lines of substantially the same width that are equidistant from each other. The overlay mark 206A may also include a grating of second features 1002 that is separated from the grating of the first features 1001. In some embodiments, the shapes and the arrangement of the second features 1002 are similar to those of the first features 1001, and thus relevant details will not be repeated.

The overlay marks 206 further include an overlay mark 206B. Similar to the overlay mark 206A, the overlay mark 206B also includes a grating of first features 1001 and a grating of second features 1002. The overlay mark 206B further includes a grating of third features 1003, in which the third features 1003 are disposed periodically in parallel along the second direction (e.g., Y direction in FIG. 2B), and each of the third features 1003 has a lengthwise direction along the first direction (e.g., X direction in FIG. 2B) that is substantially perpendicular to the second direction. The overlay mark 206A may also include a grating of fourth features 1004. In some embodiments, the shapes and the arrangement of the fourth features 1004 are similar to those of the third features 1003, and thus relevant details will not be repeated.

The overlay marks 206 further include an overlay mark 206C. In some embodiments, the overlay mark 206C is a grating overlay mark including at least a grating of fifth features 1005, in which the fifth features 1005 are disposed periodically in parallel along a first direction (e.g., X direction in FIG. 2B), and each of the first features 1001 has a lengthwise direction along a second direction (e.g., Y direction in FIG. 2B) that is substantially perpendicular to the first direction. More specifically, each of the fifth features 1005 has a bar pattern that is formed by an unbroken opaque line and the bar patterns are formed by a grating having a plurality of spaced opaque lines of substantially the same width that are equidistant from each other. In some embodiments, the line pitch and line width of the fifth features 1005 may be different from the first features 1001 as discussed above. The overlay mark 206C may also include a grating of sixth features 1006 that is separated from the grating of the fifth features 1005. In some embodiments, the shapes and the arrangement of the sixth features 1006 are similar to those of the fifth features 1005, and thus relevant details will not be repeated.

The overlay marks 206 as discussed in FIG. 2B are merely used to explain, the present disclosure is not limited thereto. In other embodiments, the number of the overlay marks 206, the arrangement of the overlay marks 206, and the pattern (e.g., the gratings) of the overlay marks 206 may be different from those described in FIG. 2B.

Referring to FIG. 2A, the overlay marks 206 may penetrate through the ESL 201 and the IMD layer 202, and may be in contact with the ILD layer 110. The overlay marks 206 and the interconnect features 204 may include a same material, and may be formed using a same process. For example, both of the overlay marks 206 and the interconnect features 204 are metal patterns. In some embodiments, the overlay marks 206 and the interconnect features 204 may be formed by, for example, patterning the ESL 201 and the IMD layer 202 to form openings in the ESL 201 and the IMD layer 202, in which the openings define the patterns of the interconnect features 204 and the overlay marks 206. Conductive material is deposited to fill the openings, and a planarization process, such as CMP, is performed to remove excess conductive material outside the openings. The conductive material may include metal such as copper (Cu), aluminum (Al), tungsten (W), combinations thereof, or the like, and may be formed using suitable deposition process.

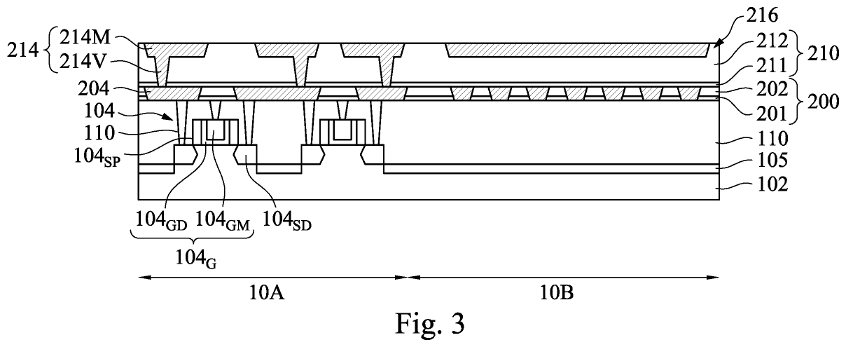

Reference is made to FIG. 3. A metallization layer 210 is formed over the structure shown in FIG. 2A. In some embodiments, the metallization layer 210 includes an etch stop layer (ESL) 211 and an inter-metal dielectric (IMD) layer 212 over the ESL 211. The ESL 211 and the IMD layer 212 may be similar to the ESL 201 and the IMD layer 202, respectively, and thus relevant details will not be repeated for brevity.

The metallization layer 210 further includes several interconnect features 214, in which each of the interconnect features 214 may penetrate through the ESL 211 and the IMD layer 212, and may be electrically connected to corresponding interconnect features 204. In the embodiments shown in FIG. 3, the interconnect features 214 are in physical contact with corresponding interconnect features 204. In some embodiments, the interconnect features 214 are located within the device region 10A of the substrate 102 of the wafer W. That is, the interconnect features 204 are not formed within the non-device region 10B of the substrate 102 of the wafer W.

In some embodiments, each of the interconnect features 214 includes a via portion 214V and a metal line portion 214M over the via portion 214V. Here, the term “via portion” may be the portion having longest dimensions extending vertically, and the term “metal line portion” may be the portion having longest dimensions extending laterally, and thus the via portions 214V conduct current vertically and are used to electrically connect two conductive features located at vertically adjacent levels, whereas the metal line portions 214M conduct current laterally and are used to distribute electrical signals and power within one level.

The metallization layer 210 further includes several overlay marks 216 located within the non-device region 10B (e.g., overlay mark region) of the substrate 102 of the wafer W. The top view of the overlay marks 216 may be similar to the top view of overlay marks 206 as described with respect to FIG. 2B. However, the arrangement of the overlay marks 216, and the pattern (e.g., the gratings) of the overlay marks 216 may be different from those of the overlay marks 206 as described in FIG. 2B. In some embodiments, bottom surface of each overlay mark 216 may be substantially level with bottom surface of the metal line portion 214M of each interconnect feature 214. In some embodiments, bottom surface of each overlay mark 216 may be higher than bottom surface of the ESL 211 and bottom surface of IMD layer 212.

In some embodiments, the interconnect features 214 and the overlay marks 216 may be formed using a dual damascene process. For example, a first patterning process is performed on the IMD layer 212 to form trench openings within the IMD layer 212, in which the trench openings define the patterns of the metal line portions 214M of the interconnect features 214 and the overlay marks 216. Afterwards, a second patterning process is performed on the IMD layer 212 within the device region 10A of the substrate 102, so as to form via openings in the IMD layer 212 and the ESL 211, in which the via openings are spatial communication with corresponding trench openings, and the via openings define the patterns of the via portions 214V of the interconnect features 214. Conductive material is deposited to fill the trench openings and the via openings, and a planarization process, such as CMP, is performed to remove excess conductive material outside the trench openings and the via openings. The conductive material may include metal such as copper, aluminum, tungsten, combinations thereof, or the like, and may be formed using suitable deposition process.

In some embodiments, during forming the metallization layer 210, overlay error is measured by using the overlay marks 206 of the metallization layer 200, and the alignment accuracy is determined based on the measured overlay error. The metallization layer 210 is formed based on the measured overlay error from the overlay marks 206 of the metallization layer 200, such that the interconnect features 214 of the metallization layer 210 are properly aligned with the corresponding interconnect features 204.

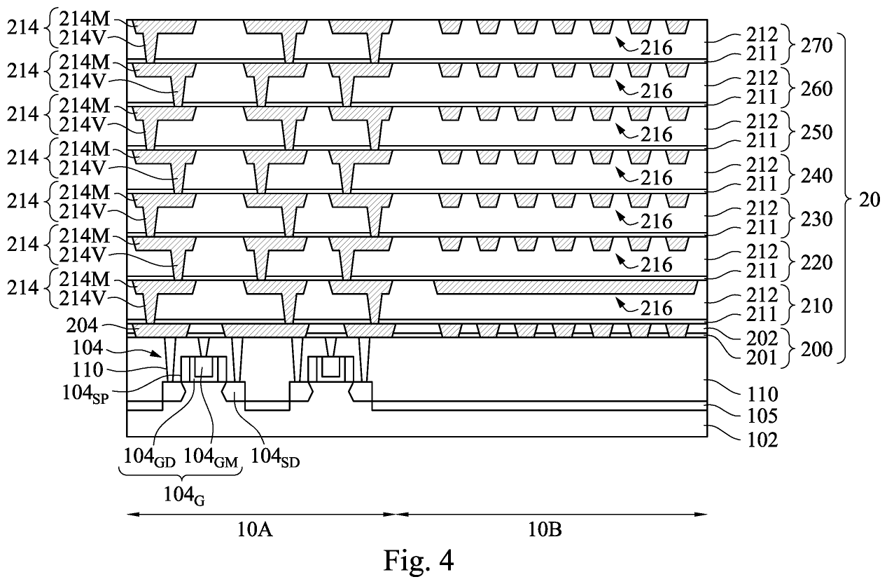

Reference is made to FIG. 4. A metallization layer 220 is formed over the structure shown in FIG. 3. Afterwards, metallization layer 230, 240, 250, 260, and 270 are sequentially formed over the metallization layer 220. The metallization layer 210, 220,230, 240, 250, 260, and 270 are collective referred to as a back-end-of-line (BEOL) structure. In some embodiments, each of the metallization layers 220, 230, 240, 250, 260, and 270 may include ESL 211, IMD layer 212, interconnect features 214, and overlay marks 216 that are similar to those described in FIG. 3, and thus relevant details will not be repeated for brevity. It is noted that although the interconnect features 214 and overlay marks 216 of the metallization layers 210 to 270 are labeled the same, the patterns and arrangement of the interconnect features 214 and overlay marks 216 of one of the metallization layers 210 to 270 may be different from the patterns and arrangement of the interconnect features 214 and overlay marks 216 of another one of the metallization layers 210 to 270. In some embodiments, the interconnect features 204 of the metallization layer 200 and the interconnect features 214 of the metallization layers 220,230, 240, 250, 260, and 270 are electrically connected to the devices 104 within the device region 10A of the substrate 102, and may form a functional circuit with the devices 104 within the device region 10A of the substrate 102. On the other hand, the overlay marks 206 of the metallization layer 200 and the overlay marks 216 of the metallization layers 220,230, 240, 250, 260, and 270 are used to metrology purpose, and are electrically isolated from the devices 104 within the device region 10A of the substrate 102.

In some embodiments, during forming the metallization layers 220 to 270, overlay error is measured by using the overlay marks 206 of an underlying metallization layer, and the alignment accuracy is determined based on the measured overlay error. For example, during forming the metallization layer 250, overlay error is measured by using the overlay marks 216 of the underlying metallization layer 240. The metallization layers 220 to 270 are formed based on the measured overlay error from the overlay marks 216 of the underlying metallization layer, such that the interconnect features 214 of the metallization layers 220 to 270 are properly aligned with the corresponding interconnect features 214 of the underlying metallization layer.

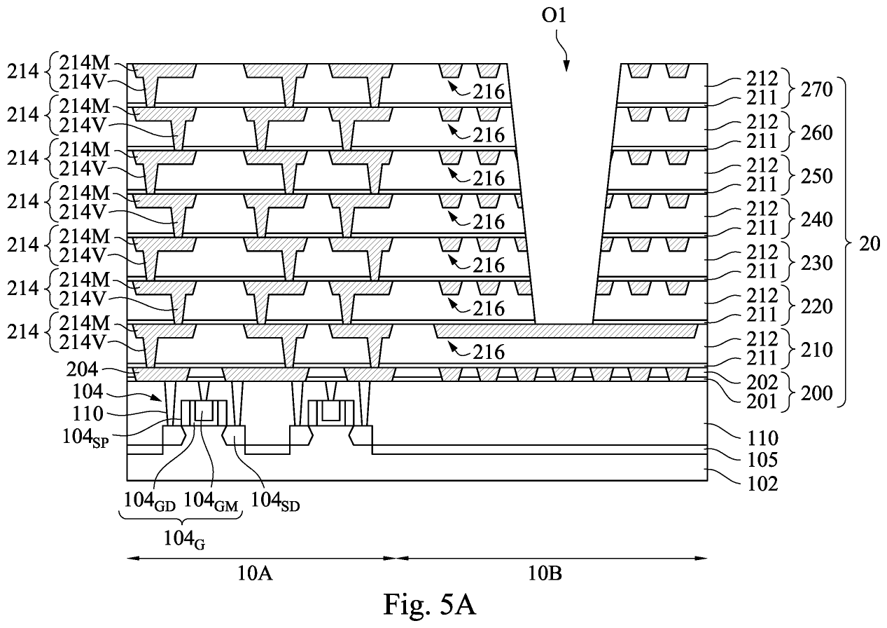

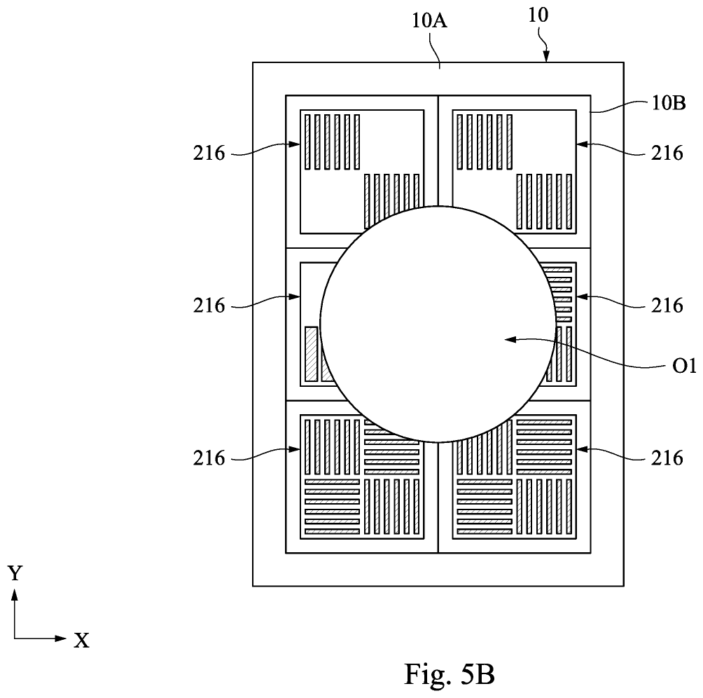

Reference is made to FIGS. 5A and 5B, in which FIG. 5A is a cross-sectional view of a die region of a wafer, and FIG. 5B is a top view of a die region of a wafer. A patterning process is performed on top surface of the BEOL structure 20, so as to form an opening O1 extending through the metallization layers 220, 230, 240, 250, 260, and 270. In greater detail, the opening O1 is formed within the non-device region 10B of the substrate 102, and the opening O1 may penetrate through the overlay marks 216 of each of the metallization layers 220, 230, 240, 250, 260, and 270. In some embodiments, portions of the conductive materials of the overlay marks 216 of each of the metallization layers 220 may be exposed through the opening O1.

In the depicted embodiments, the patterning process may stop when bottom end of the opening O1 exposes the top surface of the overlay marks 216 of the metallization layer 210, while the present disclosure is not limited thereto. In the cross-sectional view of FIG. 5A, the opening O1 has a tapered profile, in which a width of the opening O1 may decrease toward the substrate 102.

FIG. 5B is an exemplary top view of the metallization layer 270, which illustrates the relationship between the opening O1 and the overlay marks 216 of the metallization layer 270. It is noted that the relationship between the opening O1 and the overlay marks 216 of other metallization layers (e.g., the metallization layers 220 to 260) may be similar to those described in FIG. 5B, and will not be repeated for brevity. In FIG. 5B, the opening O1 has a circular top profile. At least one of the overlay marks 216 is cut by the opening O1. In the embodiments of FIG. 5B, all of the overlay marks 216 are cut, at least in part, by the opening O1. That is, a portion of each of the overlay marks 216 may be removed during forming the opening O1.

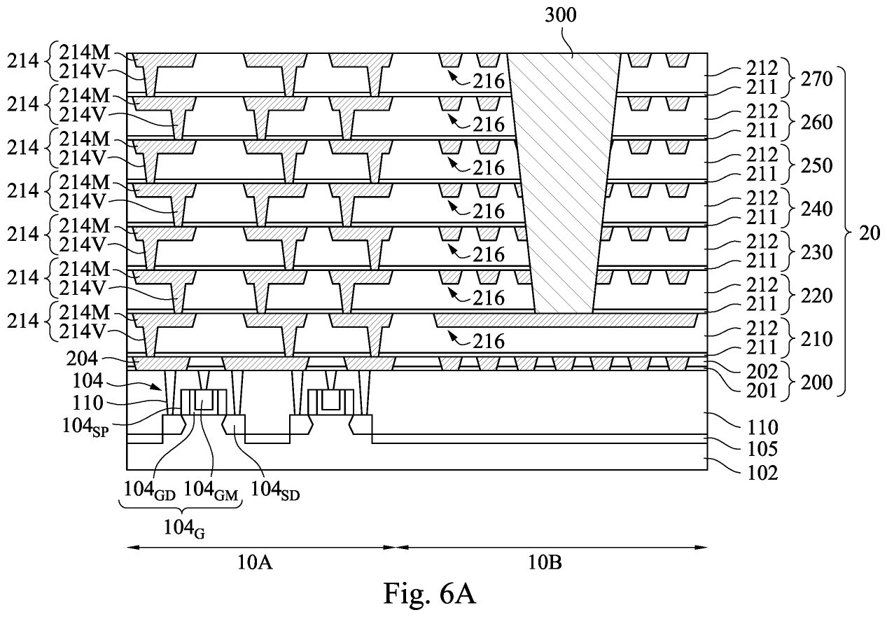

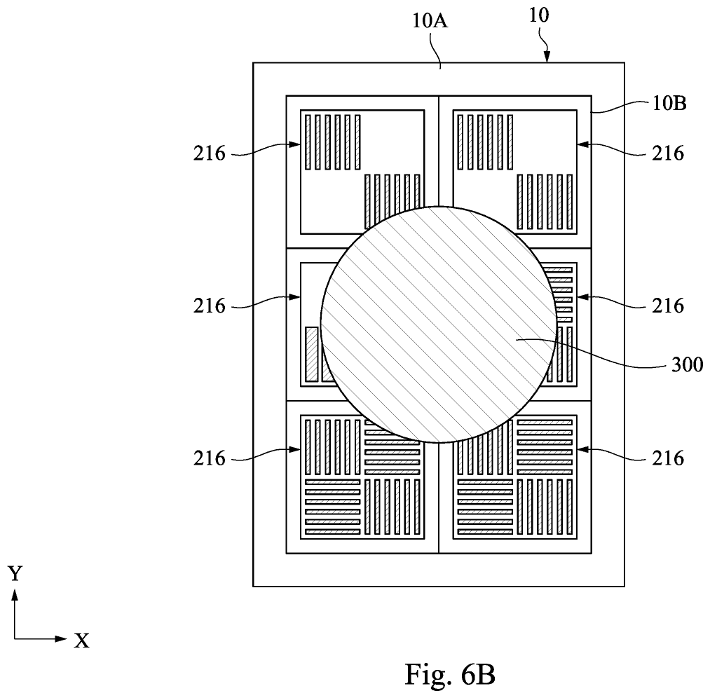

Reference is made to FIGS. 6A and 6B, in which FIG. 6A is a cross-sectional view of a die region of a wafer, and FIG. 6B is a top view of a die region of a wafer. A conductive material is filled in the opening O1 as shown in FIGS. 5A and 5B, so as to form a heat dissipation structure 300 in the opening O1. In some embodiments, the heat dissipation structure 300 may include metal such as copper (Cu), aluminum (Al), tungsten (W), combinations thereof, or the like, and may be formed using suitable deposition process. In some embodiments, the heat dissipation structure 300 may be formed by, for example, filling opening O1 with metal, and then performing a planarization process, such as CMP, to remove excess metal outside the opening O1.

In FIG. 6A, the heat dissipation structure 300 may be in contact with top surface of the overlay marks 216 of the metallization layer 210. The heat dissipation structure 300 may also be in contact with the conductive materials of the overlay marks 216 of the metallization layers 220 to 270. The heat dissipation structure 300 is a via-like structure, which has a longest dimension extending vertically, and thus the heat dissipation structure 300 can also be referred to as a heat dissipation via. The heat dissipation structure 300 may inherit the profile of the opening O1, and thus relevant details are not repeated for brevity.

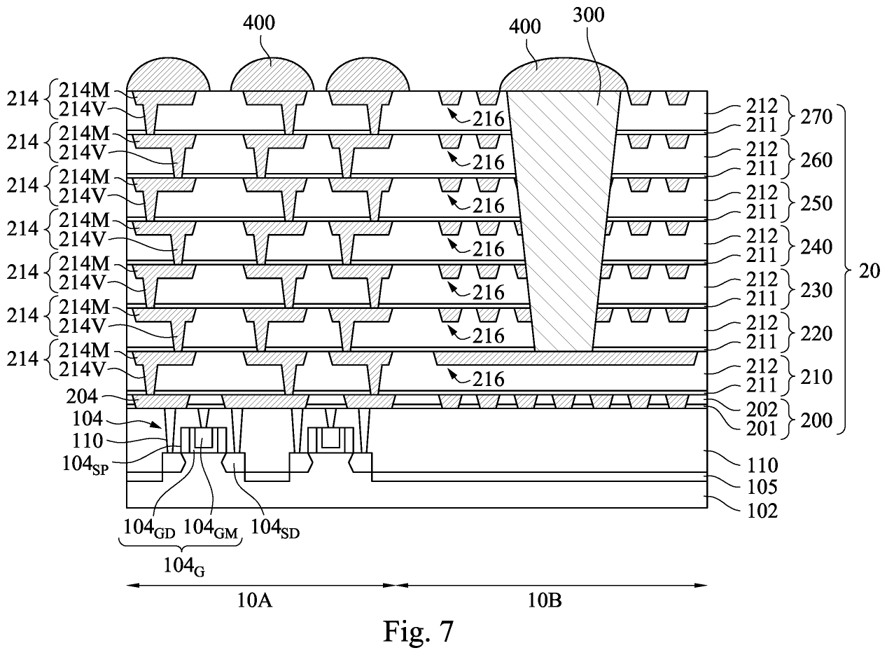

Reference is made to FIG. 7. A plurality of bumps 400 are formed over the metallization layer 270 and in contact with the interconnect features 214 and the heat dissipation structure 300. The bumps 400 may be solder ball which includes solder materials such as Sn, Ag. Cu, any combination thereof, or any other suitable material.

Embodiments of the present disclosure provide a heat dissipation structure 300 formed within the non-device region 10B of the substrate 102 of a wafer W and extending through at least two of the metallization layers (e.g., metallization layers 200 to 270). In greater detail, the heat dissipation structure 300 is formed through the in-chip metrology pads (e.g., overlay marks 216 of the metallization layers 220 to 270). With such configuration, the size of heat dissipation structure 300 is not constrained by chip layout or design rules of each layer within the device region 10A of the substrate 102 of a wafer W. In addition, the heat dissipation structure 300 can punch through “used in-chip metrology pads”, and thus no additional chip area is needed. As a result, the heat dissipation efficiency of the semiconductor chip may be improved, and the device performance will be improved accordingly.

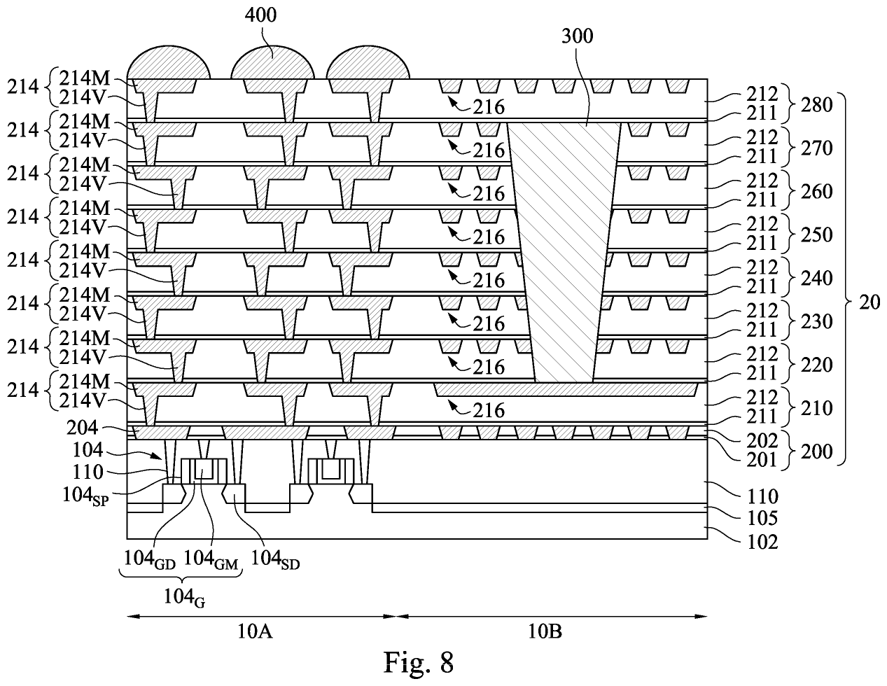

FIG. 8 illustrates a semiconductor die in accordance with some embodiments of the present disclosure. It is noted that some elements of FIG. 8 are similar to those described with respect to FIGS. 2A to 7, such elements are labeled the same, and relevant details are not repeated for brevity. As discussed in FIGS. 6A and 6B, the heat dissipation structure 300 is formed in the metallization layers 220 to 270. After the metallization layers 220 to 270 are formed, a metallization layer 280 is formed over the metallization layer 270, as shown in FIG. 8. In some embodiments, the metallization layer 280 may include ESL 211, IMD layer 212, interconnect features 214, and overlay marks 216 that are similar to those described in FIG. 3, and thus relevant details will not be repeated for brevity. Accordingly, top surface of the heat dissipation structure 300 is covered by the metallization layer 280. In some embodiments, the heat dissipation structure 300 is covered by the ESL 211 and the IMD layer 212 of the metallization layer 280.

After the metallization layer 280 is formed, a plurality of bumps 400 are formed over the metallization layer 280 and in contact with the interconnect features 214 of the metallization layer 280.

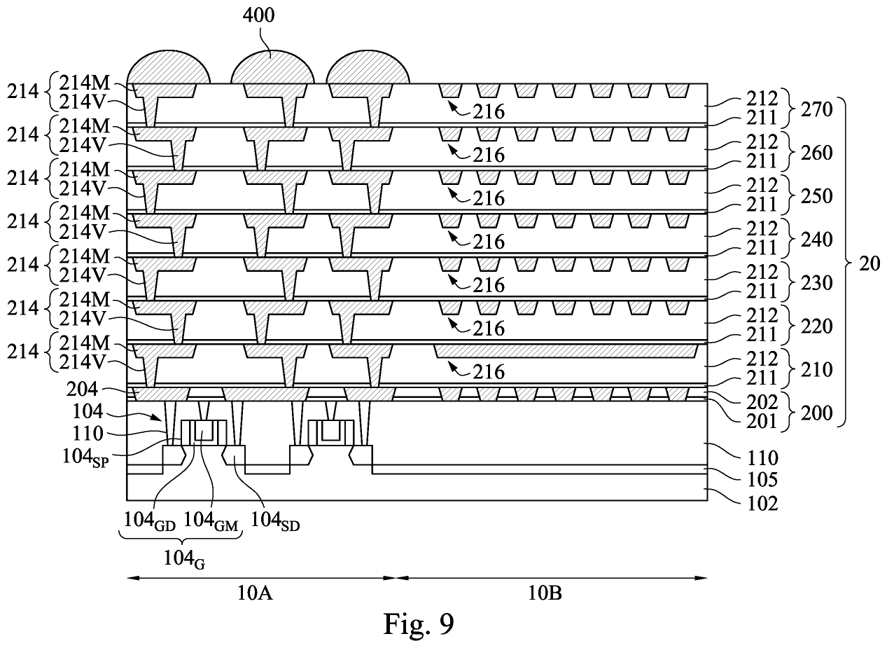

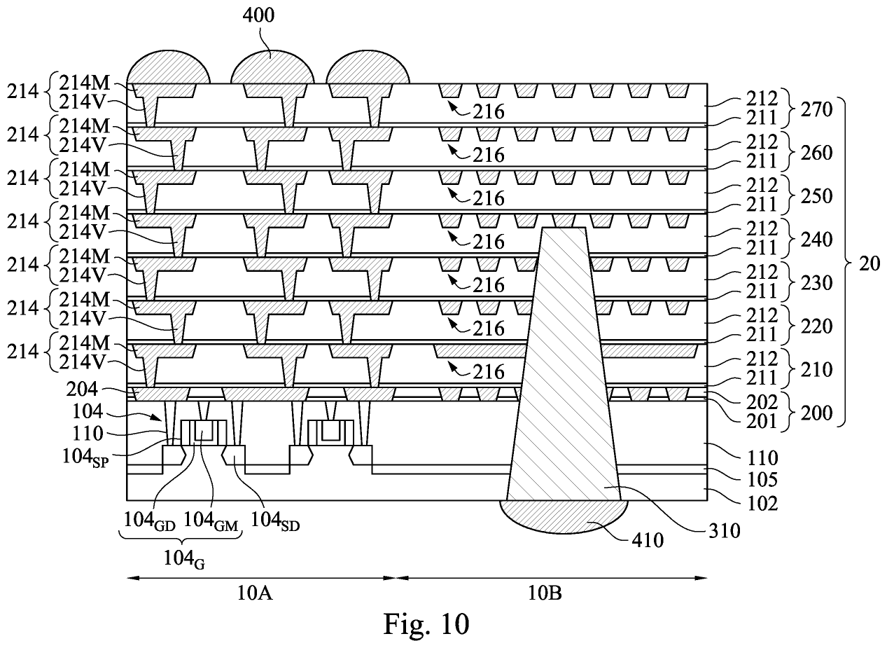

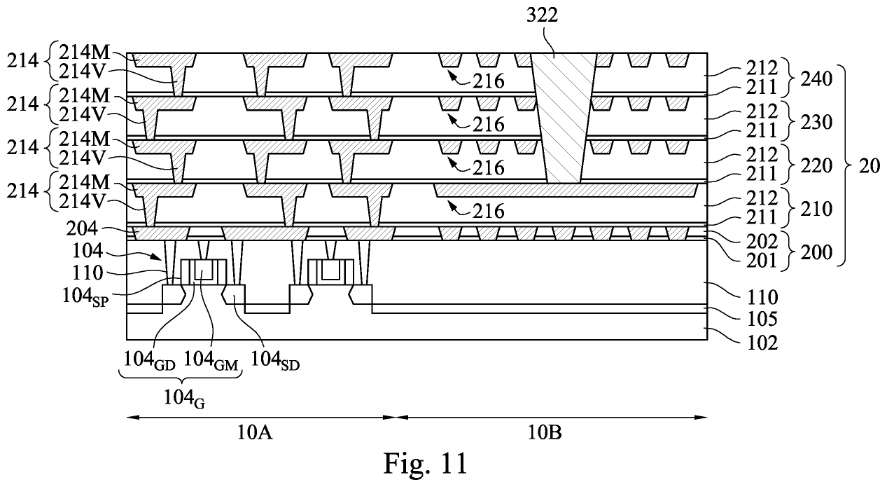

FIGS. 9 to 10 illustrate a semiconductor die in various stages of fabrication in accordance with some embodiments of the present disclosure. It is noted that some elements of FIGS. 9 to 10 are similar to those described with respect to FIGS. 2A to 7, such elements are labeled the same, and relevant details are not repeated for brevity.

Reference is made to FIG. 9. FIG. 9 is different from FIG. 7, in that the heat dissipation structure 300 of FIG. 7 is omitted in FIG. 9. That is, the processes as discussed in FIGS. 5A to 6B may be skipped during forming the structure shown in FIG. 9.

Reference is made to FIG. 10. A heat dissipation structure 310 is formed in the structure of FIG. 9. In greater detail, the heat dissipation structure 310 is formed in the structure of FIG. 9 from the backside of the non-device region 10B of the substrate 102. As a result, the heat dissipation structure 310 may extend through the substrate 102, the STI regions 105, the ILD layer 110, and the metallization layers 200, 210, 220, 230, and 240. The heat dissipation structure 310 may be in contact with bottom surface of the overlay marks 216 in the metallization layer 240. The heat dissipation structure 310 may also be in contact with the conductive materials of the overlay marks 206 of the metallization layer 200, and the overlay marks 216 of the metallization layers 220 to 230.

The heat dissipation structure 310 may be formed by, for example, flipping over the structure of FIG. 9 by 180 degrees. A patterning process is performed on the backside of the substrate 102, so as to form an opening extending through the substrate 102, the STI regions 105, the ILD layer 110, and the metallization layers 200, 210, 220, 230, and 240. Afterward, metal is filled in the opening to form the heat dissipation structure 310. In some embodiments, the heat dissipation structure 310 has a tapered profile, in which a width of the heat dissipation structure 310 may decreases as a distance from the substrate 102 increases. In some embodiments, a bottom surface of the heat dissipation structure 310 may be level with a bottom surface of the substrate 102.

After the heat dissipation structure 310 are formed. A bump 410 is formed on the backside of the substrate 102 and in contact with the heat dissipation structure 310. Material of the bump 410 may be similar to the material of the bump 400, and thus relevant details are not repeated.

FIGS. 11 to 13 illustrate a semiconductor die in various stages of fabrication in accordance with some embodiments of the present disclosure. It is noted that some elements of FIGS. 11 to 13 are similar to those described with respect to FIGS. 2A to 7, such elements are labeled the same, and relevant details are not repeated for brevity.

Reference is made to FIG. 11. After the metallization layer 240 is formed, a heat dissipation structure 322 is formed extending through the metallization layers 220, 230, and 240, and may be in contact with top surfaces of the overlay marks 216 of the metallization layer 210. The heat dissipation structure 322 may be formed using a similar process as discussed with respect to the heat dissipation structure 300, and thus relevant are not repeated. The heat dissipation structure 322 has a tapered profile, in which a width of the heat dissipation structure 322 may decreases toward the substrate 102.

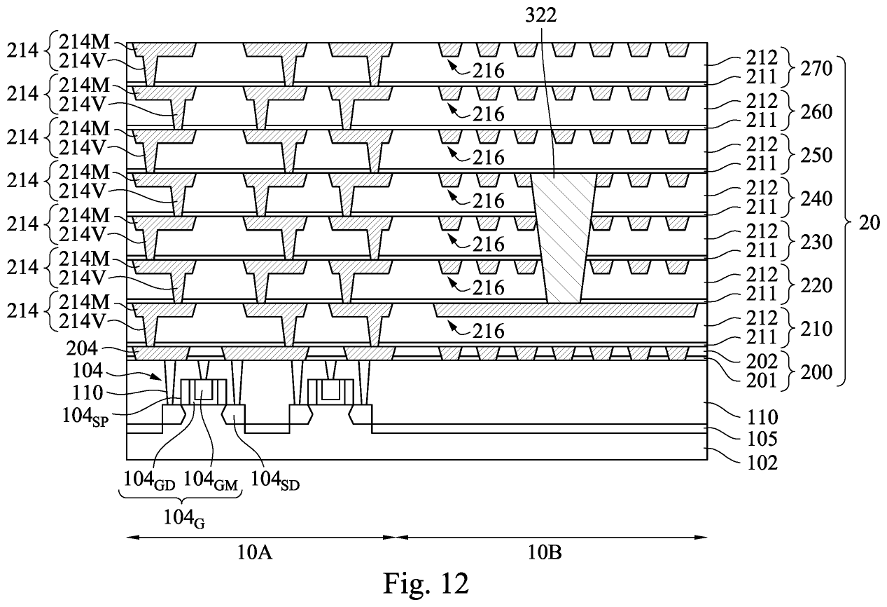

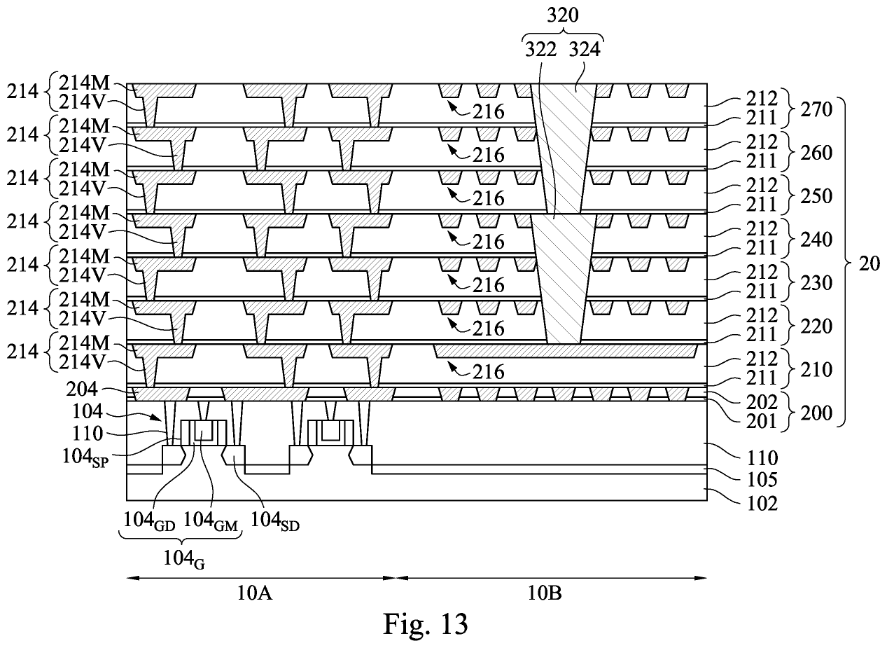

Reference is made to FIG. 12. After the heat dissipation structure 322 is formed, metallization layers 250, 260, and 270 are formed over the metallization layer 240. In some embodiments, the bottom surface of the ESL 211 of the metallization layers 250 may be in contact with top surface of the heat dissipation structure 322.

Reference is made to FIG. 13. After the metallization layers 250, 260, and 270 are formed, a heat dissipation structure 324 is formed extending through the metallization layers 250, 260, and 270, and is in contact with top surface of the heat dissipation structure 322. The heat dissipation structure 324 may be formed using a similar process as discussed with respect to the heat dissipation structure 300, and thus relevant are not repeated. The heat dissipation structure 324 has a tapered profile, in which a width of the heat dissipation structure 324 may decreases toward the substrate 102. Bottom surface of the heat dissipation structure 324 is in contact with top surface of the heat dissipation structure 322. In some embodiments, the bottom surface of the heat dissipation structure 324 is narrower than top surface of the heat dissipation structure 322. The heat dissipation structures 322 and 324 may be collectively referred to as a heat dissipation structure 320. In some embodiments, the heat dissipation structures 322 and 324 may also be referred to as first and second portions of the heat dissipation structure 320. Although not shown in FIG. 13, bump (e.g., the bump 400 shown in FIG. 7) may also be formed over the metallization layer 270 and in contact with the heat dissipation structure 320.

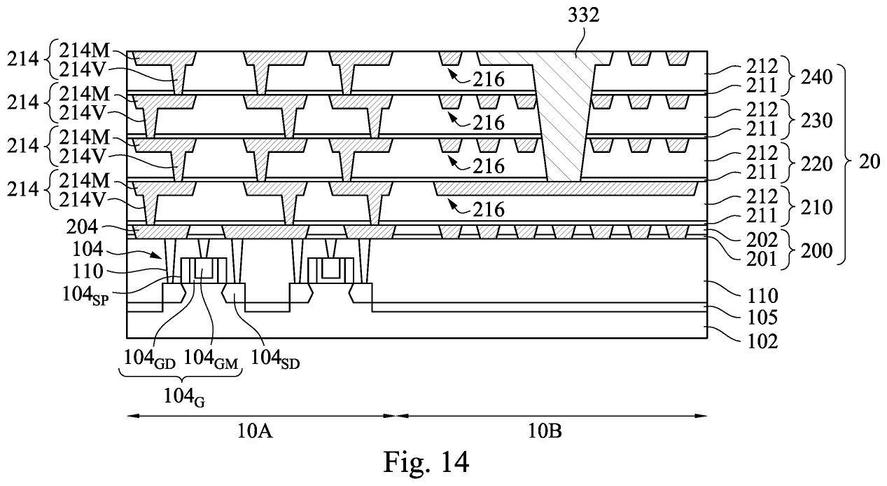

FIGS. 14 to 16 illustrate a semiconductor die in various stages of fabrication in accordance with some embodiments of the present disclosure. It is noted that some elements of FIGS. 11 to 13 are similar to those described with respect to FIGS. 2A to 7, such elements are labeled the same, and relevant details are not repeated for brevity.

Reference is made to FIG. 14. After the metallization layer 240 is formed, a heat dissipation structures 332 is formed extending through the metallization layers 220, 230, and 240, and may be in contact with top surfaces of the overlay marks 216 of the metallization layer 210. In some embodiments, the heat dissipation structures 332 may include a narrower portion and a wider portion over the narrower portion. The narrower portion of the heat dissipation structures 332 has a longest dimension extending vertically, while the wider portion of the heat dissipation structures 332 has a longest dimension extending laterally. The bottom surface of the wider portion may is wider than the top surface of the narrower.

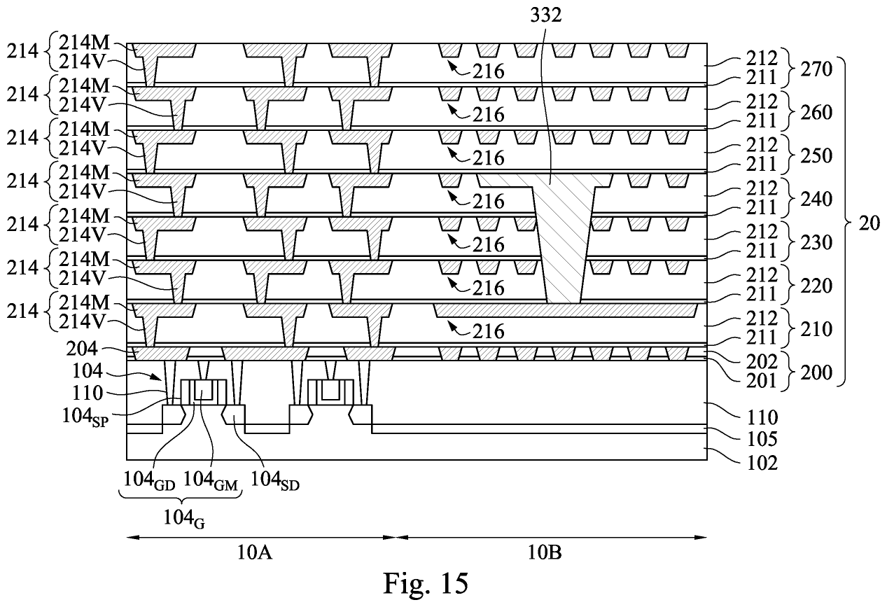

Reference is made to FIG. 15. After the heat dissipation structure 332 is formed, metallization layers 250, 260, and 270 are formed over the metallization layer 240. In some embodiments, the bottom surface of the ESL 211 of the metallization layers 250 may be in contact with top surface of the heat dissipation structure 332.

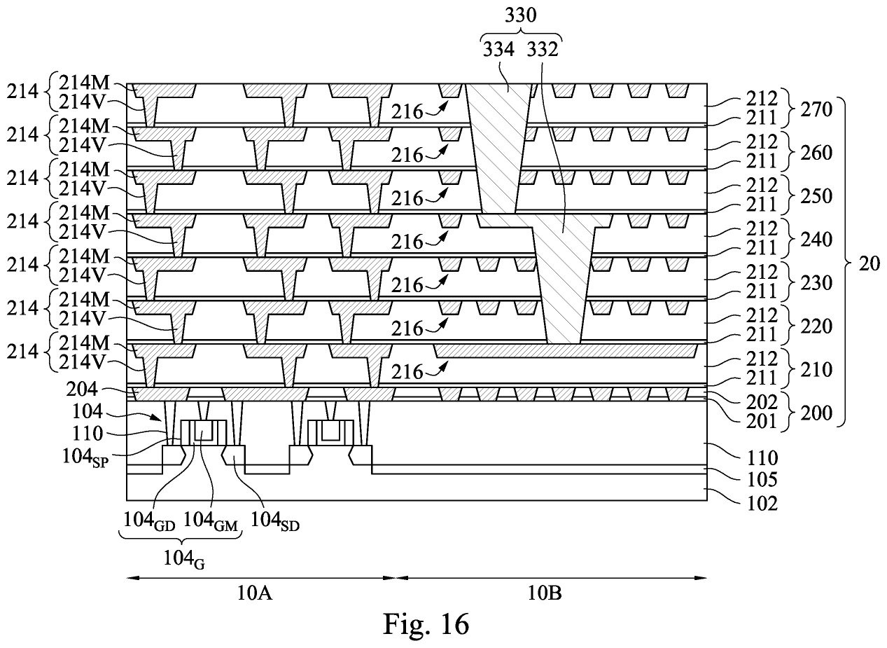

Reference is made to FIG. 16. After the metallization layers 250, 260, and 270 are formed, a heat dissipation structure 334 is formed extending through the metallization layers 250, 260, and 270, and is in contact with top surface of the heat dissipation structure 332. The heat dissipation structure 334 has a tapered profile, in which a width of the heat dissipation structure 334 may decreases toward the substrate 102. Bottom surface of the heat dissipation structure 334 is in contact with top surface of the wider portion of heat dissipation structure 332. In some embodiments, the heat dissipation structure 334 may overlaps the wider portion of heat dissipation structure 332 along the vertical direction, while the heat dissipation structure 334 non-overlaps the narrower portion of heat dissipation structure 332 along the vertical direction. The heat dissipation structures 332 and 334 may be collectively referred to as a heat dissipation structure 330. In some embodiments, the heat dissipation structure 330 can be regarded as having a first portion (e.g., the narrower portion of the heat dissipation structure 332) extending vertically, a connection portion (e.g., the wider portion of the heat dissipation structure 332) extending laterally, and the second portion (e.g., the heat dissipation structure 334) extending vertically, in which the connection portion may electrically connect the first portion to the second portion. Although not shown in FIG. 16, bump (e.g., the bump 400 shown in FIG. 7) may also be formed over the metallization layer 270 and in contact with the heat dissipation structure 330.

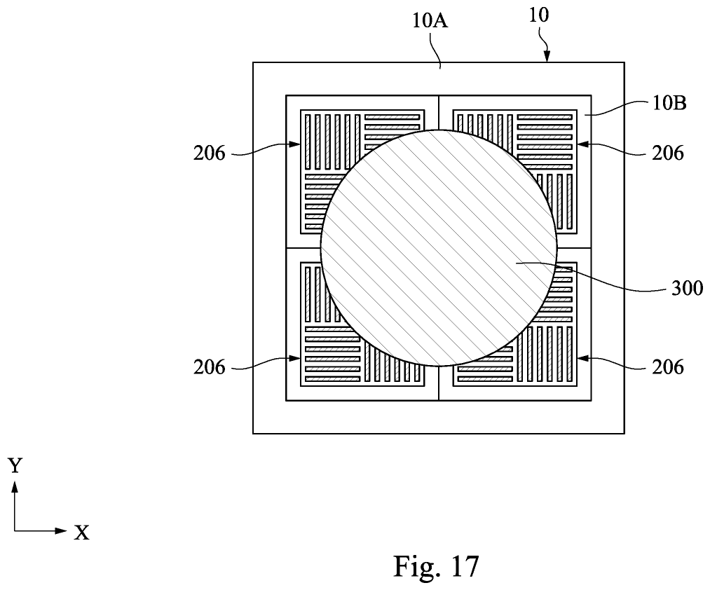

FIG. 17 is a top view of a semiconductor die in accordance with some embodiments. FIG. 17 is similar to FIG. 6B, the difference between FIG. 17 and FIG. 6B is that there are four overlay marks 216 arrange in a 4×4 matrix, and the heat dissipation structure 300 of FIG. 17 is formed through the four overlay marks 216.

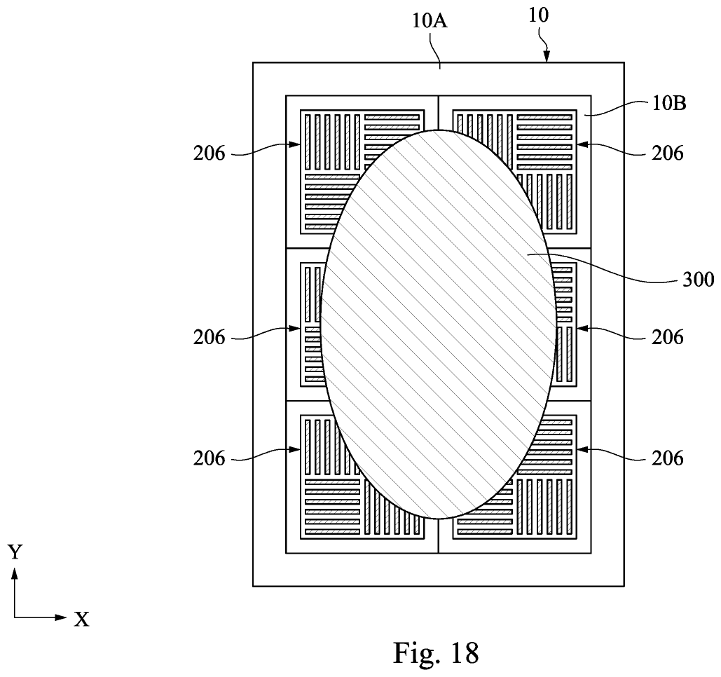

FIG. 18 is a top view of a semiconductor die in accordance with some embodiments. FIG. 18 is similar to FIG. 6B, the difference between FIG. 18 and FIG. 6B is that the heat dissipation structure 300 of FIG. 18 has an elliptical top profile. In other embodiments, the heat dissipation structure 300 may also include a rectangular top profile.

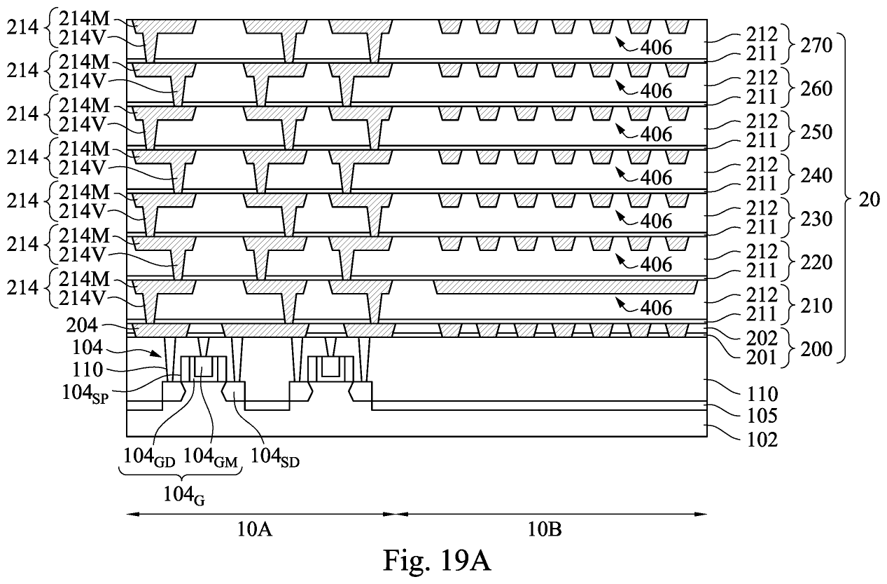

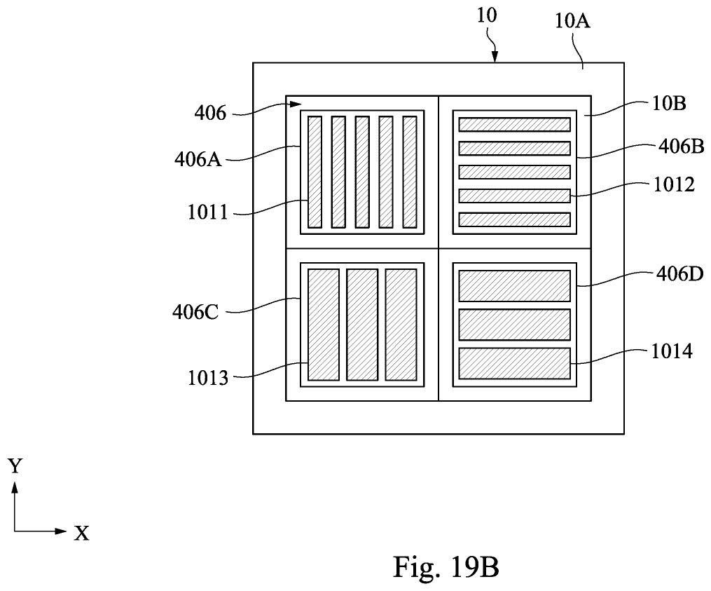

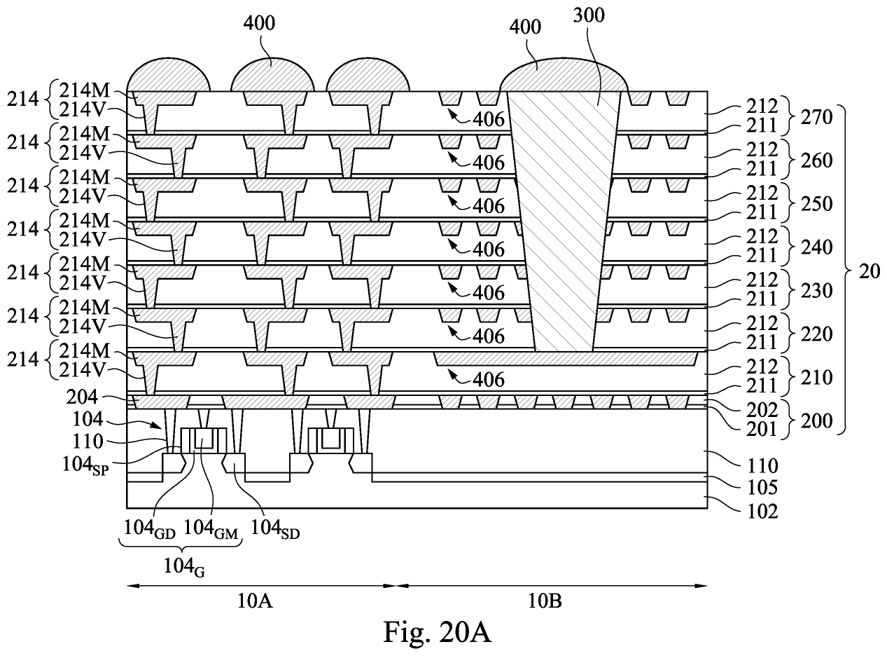

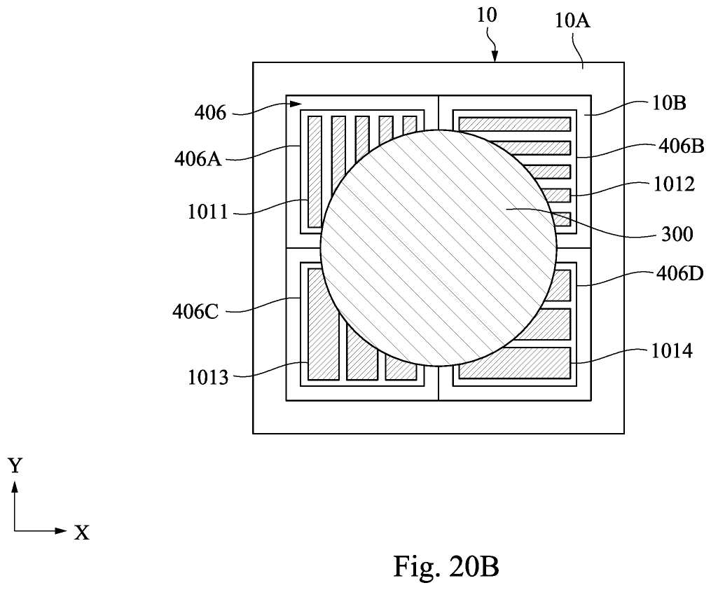

FIGS. 19A to 20B illustrate a semiconductor die in various stages of fabrication in accordance with some embodiments of the present disclosure. It is noted that some elements of FIGS. 11 to 13 are similar to those described with respect to FIGS. 2A to 7, such elements are labeled the same, and relevant details are not repeated for brevity.

Reference is made to FIGS. 19A and 19B, in which FIG. 19A is a cross-sectional view of a die region of a wafer, and FIG. 19B is a top view of a die region of a wafer. FIG. 19A is similar to FIG. 4, the difference between FIG. 19A and FIG. 4 is that the overlay marks 216 in FIG. 4 are replaced with test critical dimension (TCD) pads 406. That is, according to the previous discussion, the non-device region 10B of the substrate 102 of the wafer W is used as a test critical dimension (TCD) region. However, materials and formation method of the TCD pads 406 may be similar to those of the overlay marks 216, and will not be repeated again.

FIG. 19B is a top view of the TCD pads 406. Shown there are several TCD pads 406 arranged in a 4×4 matrix, while the disclosure is not limited thereto. The TCD pads 406 includes a TCD pad 406A, which includes first features 1011 disposed periodically in parallel along a first direction (e.g., X direction in FIG. 19B), and each of the first features 1011 has a lengthwise direction along a second direction (e.g., Y direction in FIG. 19B) that is substantially perpendicular to the first direction. The TCD pads 406 includes a TCD pad 406B, which includes second features 1012 disposed periodically in parallel along the second direction (e.g., Y direction in FIG. 19B), and each of the second features 1012 has a lengthwise direction along the first direction (e.g., X direction in FIG. 19B). The TCD pads 406 includes a TCD pad 406C, which includes third features 1013 disposed periodically in parallel along the first direction (e.g., X direction in FIG. 19B), and each of the third features 1013 has a lengthwise direction along a second direction (e.g., Y direction in FIG. 19B). The TCD pads 406 includes a TCD pad 406D, which includes fourth features 1014 disposed periodically in parallel along the second direction (e.g., Y direction in FIG. 19B), and each of the fourth features 1014 has a lengthwise direction along the first direction (e.g., X direction in FIG. 19B). In some embodiments, the first features 1011 and the second features 1012 may include a same line width and a same line pitch. The third features 1013 and the fourth features 1014 may include a same line width and a same line pitch that is different from the line widths and the line pitches of the first features 1011 and the second features 1012.

In some embodiments, during forming the metallization layers 200 to 270, feature parameters such as line width and/or line pitch of the TCD pads 406 may be measured. The line width of these structures corresponds substantially to the critical dimension (CD) of the lithographic apparatus used. That is, during forming the metallization layers 200 to 270, the critical dimension of the TCD pads 406 are measured.

Reference is made to FIGS. 20A and 20B, in which FIG. 20A is a cross-sectional view of a die region of a wafer, and FIG. 20B is a top view of a die region of a wafer. FIGS. 20A and 20B are similar to FIGS. 6A and 6B, in which heat dissipation structure 300 is formed in the BEOL structure 20. The relationship between the heat dissipation structure 300 and the TCD pads 406 is similar to the relationship between the heat dissipation structure 300 and the overlay marks 216 as discussed above, and will not be repeated again.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provides a semiconductor chip, which includes a heat dissipation structure extending through at least two metallization layers of BEOL structure. Moreover, the heat dissipation structure is formed through an in-chip metrology pads (e.g., overlay marks or TCD pads). With such configuration, the size of heat dissipation structure is not constrained by chip layout or design rules of each layer within the device region of semiconductor chip. In addition, the heat dissipation structure can punch through “used in-chip metrology pads”, and thus no additional chip area is needed. As a result, the heat dissipation efficiency of the semiconductor chip may be improved, and the device performance will be improved accordingly.

In some embodiments of the present disclosure, a semiconductor die includes a substrate, a semiconductor device, a back-end-of-line (BEOL) structure, and a heat dissipation structure. The substrate includes a device region and a non-device region. The semiconductor device is over the device region of the substrate. The BEOL structure includes a plurality of metallization layers and is over the substrate and at a level above the semiconductor device. Each of the metallization layers includes a dielectric layer, interconnect features, and metal patterns. The interconnect features is in the dielectric layer and over the device region of the substrate, in which the interconnect features are electrically connected with the semiconductor device. The metal patterns are in the dielectric layer and over the non-device region of the substrate, in which the metal patterns are electrically isolated from the semiconductor device. The heat dissipation structure is over the non-device region of the substrate and extending through at least two of the metallization layers, in which the heat dissipation structure is in contact with the metal patterns of one of the metallization layers.

In some embodiments, a top surface of the heat dissipation structure is substantially level with a top surface of the dielectric layer of a topmost one of the metallization layers.

In some embodiments, a top surface of the heat dissipation structure is covered by a dielectric layer of a topmost one of the metallization layers.

In some embodiments, the heat dissipation structure comprises a first portion and a second portion over the first portion, wherein a top surface of the first portion is wider than a bottom surface of the second portion.

In some embodiments, the heat dissipation structure includes a first portion, a second portion at a level higher than the first portion, and a connection portion between the first portion and the second portion and electrically connecting the first portion to the second portion. The second portion non-overlaps the first portion along a vertical direction.

In some embodiments, the heat dissipation structure further extends through the substrate.

In some embodiments, the metal patterns are overlay marks or test critical dimension patterns.

In some embodiments of the present disclosure, a semiconductor die includes a substrate, a semiconductor device, a back-end-of-line (BEOL) structure, and a heat dissipation structure. The substrate includes a device region and an overlay mark region. The semiconductor device is over the device region of the substrate. The BEOL structure includes a plurality of metallization layers and is over the substrate and at a level above the semiconductor device. Each of the metallization layers includes a dielectric layer, interconnect features, and overlay marks. The interconnect features are in the dielectric layer and over the device region of the substrate, in which the interconnect features are electrically connected with the semiconductor device. The overlay marks are in the dielectric layer and over the overlay mark region of the substrate. The heat dissipation structure are over the overlay mark region of the substrate, in which in a cross-sectional view the heat dissipation structure extends through at least two metallization layers, and in which in a top view at least one of the overlay marks is cut by the heat dissipation structure.

In some embodiments, the heat dissipation structure is in contact with portions of metal features of the overlay marks of at least one of the metallization layers.

In some embodiments, a bottom surface of the heat dissipation structure is in contact with overlay marks of one of the metallization layers.

In some embodiments, a bottom surface of the heat dissipation structure is substantially level with a bottom surface of the substrate.

In some embodiments, the semiconductor die further includes a bump over the BEOL structure and in contact with the heat dissipation structure.

In some embodiments, in the top view all of the overlay marks are cut by the heat dissipation structure.

In some embodiments, in the top view the heat dissipation structure has a circular top profile.

In some embodiments, in the top view the heat dissipation structure has an elliptical top profile.

In some embodiments of the present disclosure, a method includes forming a semiconductor device over a device region of a substrate; forming a back-end-of-line (BEOL) structure comprising a plurality of metallization layers over the semiconductor device, wherein each of the metallization layers comprises a dielectric layer; interconnect features in the dielectric layer and over the device region of the substrate, wherein the interconnect features are electrically connected with the semiconductor device; and metal patterns in the dielectric layer and over a non-device region of the substrate, wherein the metal patterns are electrically isolated from the semiconductor device; forming an opening in a portion of the BEOL structure over the non-device region of the substrate and extending through at least two of the metallization layers; and filling the opening with a metal.

In some embodiments, forming the opening in the portion of the BEOL structure includes performing an etching process from a top surface of the BEOL structure.

In some embodiments, forming the opening in the portion of the BEOL structure comprises performing an etching process from a backside of the substrate until the opening extends into the portion of the BEOL structure.

In some embodiments, the metal patterns are overlay marks, wherein a first one of the metallization layers is formed by using the overlay marks in a second one of the metallization layers below the first one of the metallization layers, such that the interconnect features of the first one of the metallization layers are aligned with the interconnect features of the second one of the metallization layers.

In some embodiments, the metal patterns are test critical dimension patterns, and the method further comprising measuring a critical dimension of the metal patterns during forming the BEOL structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die, comprising:
a substrate comprising a device region and a non-device region;
a semiconductor device over the device region of the substrate;
a back-end-of-line (BEOL) structure comprising a plurality of metallization layers over the substrate and at a level above the semiconductor device, wherein each of the metallization layers comprises:
a dielectric layer;
interconnect features in the dielectric layer and over the device region of the substrate, wherein the interconnect features are electrically connected with the semiconductor device; and
metal patterns in the dielectric layer and over the non-device region of the substrate, wherein the metal patterns are electrically isolated from the semiconductor device; and
a heat dissipation structure over the non-device region of the substrate and extending through at least two of the metallization layers, wherein the heat dissipation structure is in contact with the metal patterns of one of the metallization layers.

2. The semiconductor die of claim 1, wherein a top surface of the heat dissipation structure is substantially level with a top surface of the dielectric layer of a topmost one of the metallization layers.

3. The semiconductor die of claim 1, wherein a top surface of the heat dissipation structure is covered by a dielectric layer of a topmost one of the metallization layers.

4. The semiconductor die of claim 1, wherein the heat dissipation structure comprises a first portion and a second portion over the first portion, wherein a top surface of the first portion is wider than a bottom surface of the second portion.

5. The semiconductor die of claim 1, wherein the heat dissipation structure comprises:
a first portion;
a second portion at a level higher than the first portion, wherein the second portion non-overlaps the first portion along a vertical direction; and
a connection portion between the first portion and the second portion and electrically connecting the first portion to the second portion.

6. The semiconductor die of claim 1, wherein the heat dissipation structure further extends through the substrate.

7. The semiconductor die of claim 1, wherein the metal patterns are overlay marks or test critical dimension patterns.

8. A semiconductor die, comprising:
a substrate comprising a device region and an overlay mark region;
a semiconductor device over the device region of the substrate;
a back-end-of-line (BEOL) structure comprising a plurality of metallization layers over the substrate and at a level above the semiconductor device, each of the metallization layers comprises:
a dielectric layer;
interconnect features in the dielectric layer and over the device region of the substrate, wherein the interconnect features are electrically connected with the semiconductor device; and
overlay marks in the dielectric layer and over the overlay mark region of the substrate; and
a heat dissipation structure over the overlay mark region of the substrate, wherein in a cross-sectional view the heat dissipation structure extends through at least two metallization layers, and wherein in a top view at least one of the overlay marks is cut by the heat dissipation structure.

9. The semiconductor die of claim 8, wherein the heat dissipation structure is in contact with portions of metal features of the overlay marks of at least one of the metallization layers.

10. The semiconductor die of claim 8, wherein a bottom surface of the heat dissipation structure is in contact with overlay marks of one of the metallization layers.

11. The semiconductor die of claim 8, wherein a bottom surface of the heat dissipation structure is substantially level with a bottom surface of the substrate.

12. The semiconductor die of claim 8, further comprising a bump over the BEOL structure and in contact with the heat dissipation structure.

13. The semiconductor die of claim 8, wherein in the top view all of the overlay marks are cut by the heat dissipation structure.

14. The semiconductor die of claim 8, wherein in the top view the heat dissipation structure has a circular top profile.

15. The semiconductor die of claim 8, wherein in the top view the heat dissipation structure has an elliptical top profile.

16. A method, comprising:
forming a semiconductor device over a device region of a substrate;
forming a back-end-of-line (BEOL) structure comprising a plurality of metallization layers over the semiconductor device, wherein each of the metallization layers comprises:
a dielectric layer;
interconnect features in the dielectric layer and over the device region of the substrate, wherein the interconnect features are electrically connected with the semiconductor device; and
metal patterns in the dielectric layer and over a non-device region of the substrate, wherein the metal patterns are electrically isolated from the semiconductor device;
forming an opening in a portion of the BEOL structure over the non-device region of the substrate and extending through at least two of the metallization layers; and
filling the opening with a metal.

17. The method of claim 16, wherein forming the opening in the portion of the BEOL structure comprises performing an etching process from a top surface of the BEOL structure.

18. The method of claim 16, wherein forming the opening in the portion of the BEOL structure comprises performing an etching process from a backside of the substrate until the opening extends into the portion of the BEOL structure.

19. The method of claim 16, wherein the metal patterns are overlay marks, wherein a first one of the metallization layers is formed by using the overlay marks in a second one of the metallization layers below the first one of the metallization layers, such that the interconnect features of the first one of the metallization layers are aligned with the interconnect features of the second one of the metallization layers.

20. The method of claim 16, wherein the metal patterns are test critical dimension patterns, and the method further comprising measuring a critical dimension of the metal patterns during forming the BEOL structure.
